(19) United States
(12) Patent Application Publication
(10) Pub. No.: US 2025/0271468 A1
(43) Pub. Date: Aug. 28, 2025

(54) APPLY OSCILLOSCOPE NOISE COMPENSATION TO ACQUIRED WAVEFORM

(71) Applicant: Tektronix, Inc., Beaverton, OR (US)

(72) Inventor: Kan Tan, Portland, OR (US)

(21) Appl. No.: 19/053,807

(22) Filed: Feb. 14, 2025

Related U.S. Application Data
(60) Provisional application No. 63/557,882, filed on Feb. 26, 2024.

(51) Int. Cl. G01R 13/02; G01R 35/00

(52) U.S. Cl. CPC G01R 13/0272; G01R 13/0281; G01R 13/029; G01R 35/005

(57) ABSTRACT

An oscilloscope includes one or more ports to connect to a device under test (DUT) and receive a signal, one or more analog-to-digital converter (ADC) to produce a waveform of digital samples of the signal, and one or more processors to: acquire and determine a measure of a noise waveform, acquire a waveform of a repeating pattern from the ADCs and determine its frequency spectrum, identify a spectral impulse portion of the frequency spectrum, determine a measure of a flat portion of the frequency spectrum, use the measure of the flat portion and the measure of the noise waveform to produce a noise compensation ratio, scale the flat portion with the noise compensation ratio and combine it with the spectral impulse portion of the frequency spectrum to produce a noise compensated frequency spectrum, convert the noise compensated frequency spectrum to a time domain waveform to measure performance of the DUT.

### CROSS-REFERENCE TO RELATED APPLICATIONS

This disclosure is a non-provisional of and claims benefit from U.S. Provisional Application No. 63/557,882, titled “APPLY OSCILLOSCOPE NOISE COMPENSATION TO ACQUIRED WAVEFORM,” filed on Feb. 26, 2024, the disclosure of which is incorporated herein by reference in its entirety.

### TECHNICAL FIELD

This disclosure relates to test and measurement instruments, and more particularly to techniques for reducing the effects of noise in a test and measurement instrument, such as an oscilloscope.

### BACKGROUND

Accuracy of an oscilloscope's acquisition of high-speed signaling waveforms is negatively impacted by noise of the oscilloscope itself. As of this writing, the high-speed serial data signals are used extensively in data center and other applications at speeds of 32 GBaud/s PAM4 in PCIE Gen6 and 53 GBaud PAM4 in 400G Ethernet. Sec, e.g., “PCI Express Base Specification 6.0,” 2021, https://pcisig.com/specifications/2021; “IEEE 802.3ck 100 Gb/s, 200 Gb/s and 400 Gb/s Ethernet Standard,” 2022, http://www.iece802.org/3/. Transceivers for such applications are measured, and pass/fail is determined based on such measurements. The noise in the acquired waveform has larger impact on the link performance measurements such as symbol error rate, SNDR, and TDECQ for the electrical and optical signals since the margins of the tests decrease as the data rate increases. The impact may result in inaccurate measurements that fail devices that should have passed and pass devices that should have failed.

Oscilloscopes are widely used in industry to measure high-speed signals as they combine high bandwidth with versatile debug capabilities. As used here the term “RT oscilloscope” means any oscilloscope that acquires signals with real-time oversampling. The real-time oversampling typically guarantees anti-aliasing by the acquisition system design. The instrument noise of these types of oscilloscopes impacts the measured jitter, eye opening and eye closure, and other measurements. The random part of the instrument noise is scaled for measurements at a very low bit error ratio (BER). For example, the random noise gets converted to random jitter through the rising or falling edges of the signal, the standard deviation of the random jitter gets multiplied by 14 times for total jitter and eye-opening measurements at a BER of 10e-12.Usually, a major part of the instrument noise is random.

U.S. Pat. App. Pub. No. 2023/0280373, titled “Signal processing method and signal processing system,” published Sep. 7, 2023, hereinafter “Ramian,” describes a method that uses the knowledge of the noise from the device under test (DUT) to get the cleaner signals for measurements such as error vector magnitude (EVM).

### BRIEF DESCRIPTION OF THE DRAWINGS

FIG. 1 shows an embodiment of an oscilloscope device.

FIG. 2 shows an example of PCIE (Peripheral Component Interconnect Express (PCIE) Generation 6 compliance pattern waveform.

FIG. 3 shows an example of a waveform frequency spectrum.

FIG. 4 shows a zoomed in view of a waveform frequency spectrum.

FIG. 5 shows a zoomed in view of a waveform frequency spectrum with noise compensation.

FIG. 6 shows examples of eye diagrams before and after noise compensation.

### DETAILED DESCRIPTION

The embodiments here involve Real-Time (RT) oscilloscopes that do not use the knowledge of the DUT noise. Instead, the oscilloscope of the embodiments uses the knowledge of the noise of the measurement instrument. The oscilloscope only needs to characterize the instrument noise once, and then the oscilloscope uses the noise characterization to test and measure multiple DUTs.

In most test settings, the oscilloscope can acquire multiple repeats of a test pattern in short period of time because the oscilloscope samples the signal in real time. For example, for a 53 GigaBaud (GBaud) PAM4 (Pulse Amplitude Modulation 4) signal, the oscilloscope can acquire 53 million symbols in one millisecond. The high bandwidth oscilloscopes usually have large acquisition memory, for example, up to 1 Giga sample points per channel. For a typical PRBS13Q (Pseudo-Random Binary Sequence length 13) test pattern which has 8191 symbols, an oscilloscope can acquire 100 repeats of the pattern running at 53 GBaud in 16 microseconds. In comparison, it could take seconds for a sampling oscilloscope to acquire just one repeat of the pattern. This comprises just one example of a repeating pattern that the oscilloscope can acquire.

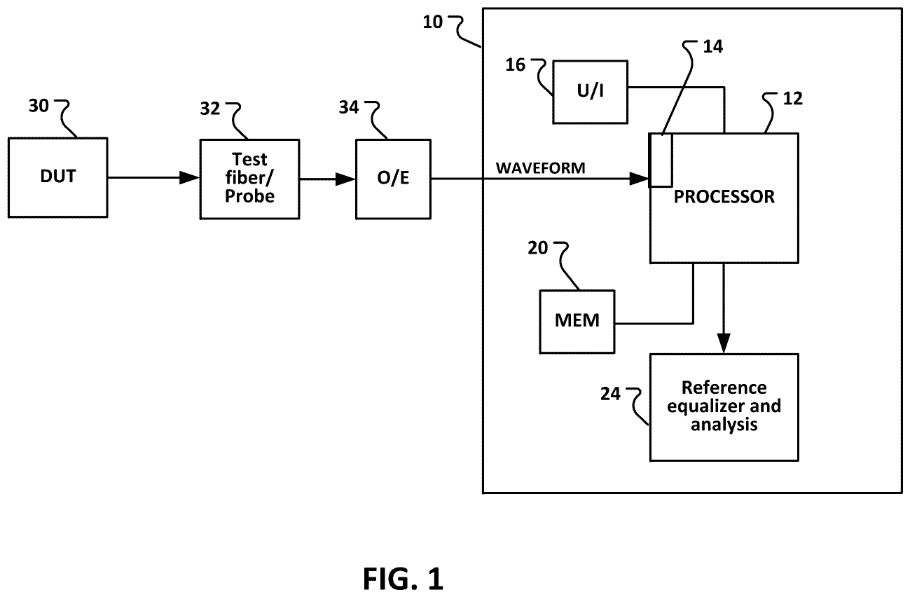

FIG. 1 shows an embodiment of an oscilloscope in a testing setup for a device under test (DUT) 30. The setup includes the possibility that the DUT comprises an optical transmitter, so the test setup includes an optical to electrical (O/E) converter 34 as an accessory to the oscilloscope. If the signals from the DUT are not optical, the setup would not include the O/E converter 34. The oscilloscope 10 receives a signal from DUT 30 through an instrument probe or a fiber for optical signal or a cable for electrical signal 32. In the case of an optical transmitter, the probe will typically comprise a test fiber coupled to an optical to electrical converter 34 that provides a signal to the test and measurement instrument through one or more ports 14. Two ports may be used for differential signaling, while one port is used for single-ended signaling. The instrument samples and digitizes the incoming waveforms. Real-time oscilloscopes generally use a software clock recovery process and do not employ any type of clock recovery hardware.

The oscilloscope has one or more processors represented by processor 12, a memory 20, and a user interface 16. The memory may store executable instructions in the form of code that, when executed by the processor, causes the processor to perform tasks. User interface 16 of the test and measurement instrument allows a user to interact with the instrument 10, such as to input settings, configure tests, etc. The test and measurement instrument may also include a reference equalizer and analysis module 24.

The one or more processors of the oscilloscope will first characterize the noise waveform of the oscilloscope in absence of an input. The characterization occurs before any measurements are performed. U.S. patent application Ser. No. 18/478,556, titled “ADAPTIVE INSTRUMENT NOISE REMOVAL,” filed Sep. 29, 2023, hereinafter “Tan,” the contents of which are hereby incorporated by reference into this disclosure, describes an embodiment of this process. Many factors can impact the oscilloscope random noise, such as sample rate, oscilloscope bandwidth, vertical gain and offset settings, signal path compensation (SPC), etc. In the discussion herein, the oscilloscope noise measurement comprises the root mean square (RMS) of the scope noise denoted as scopeNoiseSpectrumRMS. The RMS measurement of scope noise is used for optical signals, whereas the standard deviation measurement of the scope noise is used for electrical signals. In this document, the scope noise scopeNoiseSpectrumRMS represents either RMS or standard deviation depending on the signal type being optical or electrical.

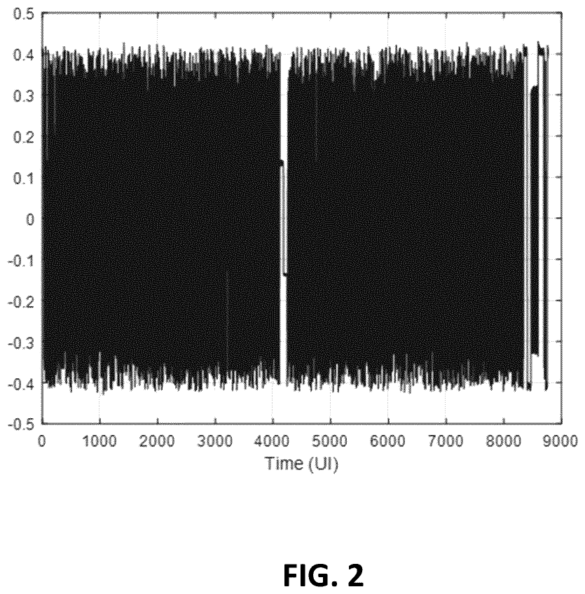

The oscilloscope then acquires a waveform with multiple repeats of the data pattern from the DUT. For example, one repeat of the 32 GBaud PAM4 PCIE Gen 6 (Peripheral Component Interface Express Generation 6) compliance pattern waveform is shown in FIG. 2. This pattern is used as a standardized pattern for measuring the compliance of the DUT to the required performance under the standard.

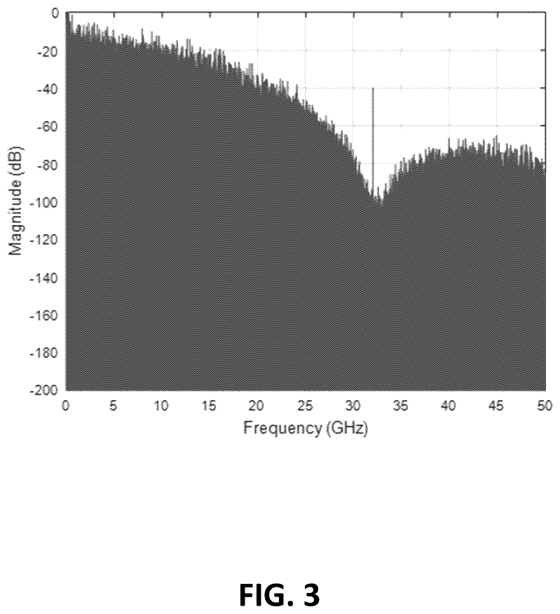

Once the oscilloscope has acquired multiple repeats of the pattern, it determines the spectrum of the waveform. This generally involves converting the waveform from the time domain to the frequency domain, such as through Fast Fourier Transform (FFT). FIG. 3 shows the spectrum of the acquired waveform of the PCIE Gen6 signal.

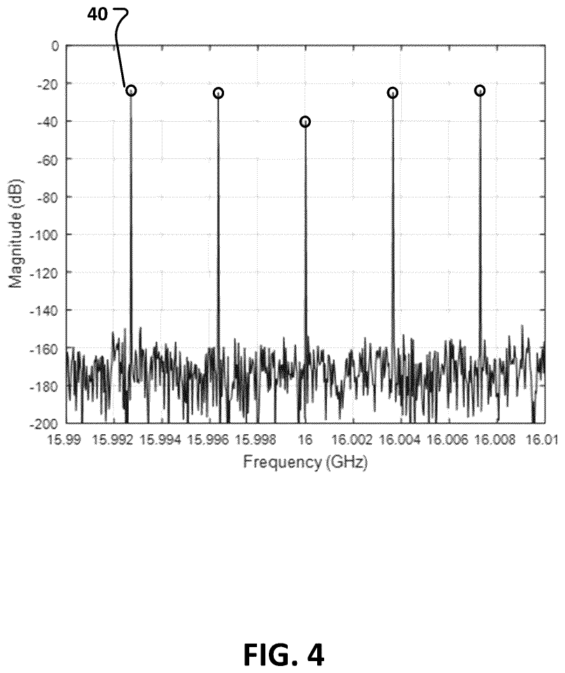

The one or more processors in the scope then identify the spectral impulses that are associated with the repeating pattern. FIG. 4 shows a zoomed-in version of the spectrum of FIG. 3 around 16 GHz, showing peaks or spectral impulses such as 40 highlighted with circles to stand out from the spectral floor. This identification essentially separates the waveform spectrum into two parts. One part comprises the spectrum Yᵢₘₚᵤₗₛₑ related to the signal pattern, visible as the spectral impulses. The other part of the spectrum Y_{flat} comprises the remaining spectrum components that are not related to the signal pattern. See John Proakiss and Dimitris Manolakis, “Digital signal processing: principle, algorithms, and applications,” Prentice-Hall, 1996.

The process then measures, such as using RMS, of the spectrum Y_{flat}, that has no impulses, denote it as signalFlatSpectrumRMS. The noise compensation ratio depends upon the flat signal spectrum measurement and the oscilloscope noise measurement. In one embodiment the scope noise compensation ratio equals:

$$scopeNoiseCompRatio = \frac{\sqrt{signalFlatSpectrum {RMS}^{2} - scopeNoise {RMS}^{2}}}{signalFlatSpectrum RMS} .$$

In this formula, the scope noise is compensated 100%. The scope noise can also be compensated partially. For example, 80% of the scope noise is compensated. To do that, the signalFlatSpectrumRMS term in the formula is scaled by 80%.

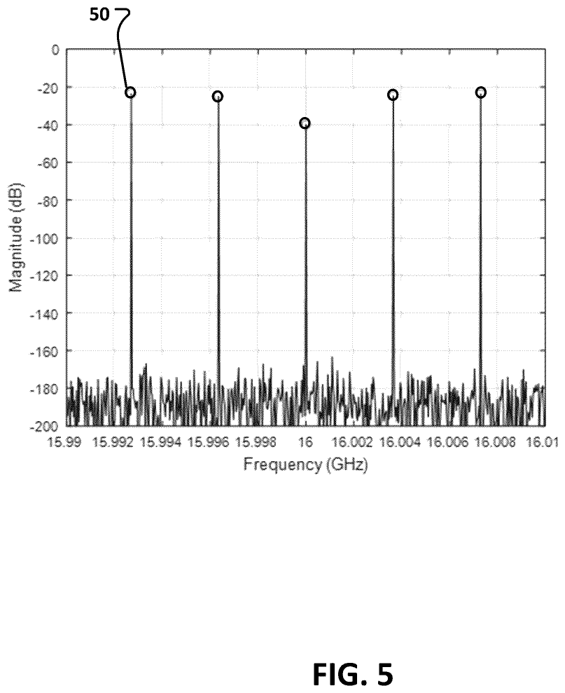

The process then scales the flat portion of the waveform spectrum corresponding to the spectrum Y_{flat} with the scope noise compensation ratio, and then combines the scaled flat spectrum component with the waveform component corresponding to the spectrum impulses associated with the pattern. This results in the oscilloscope noise compensated waveform spectrum. FIG. 5 shows a zoomed-in view of the oscilloscope noise compensated waveform spectrum. Note that the spectral impulses such as 50 are the same in FIG. 4 and FIG. 5, but the spectral noise floor is lower in FIG. 5 than in FIG. 4.

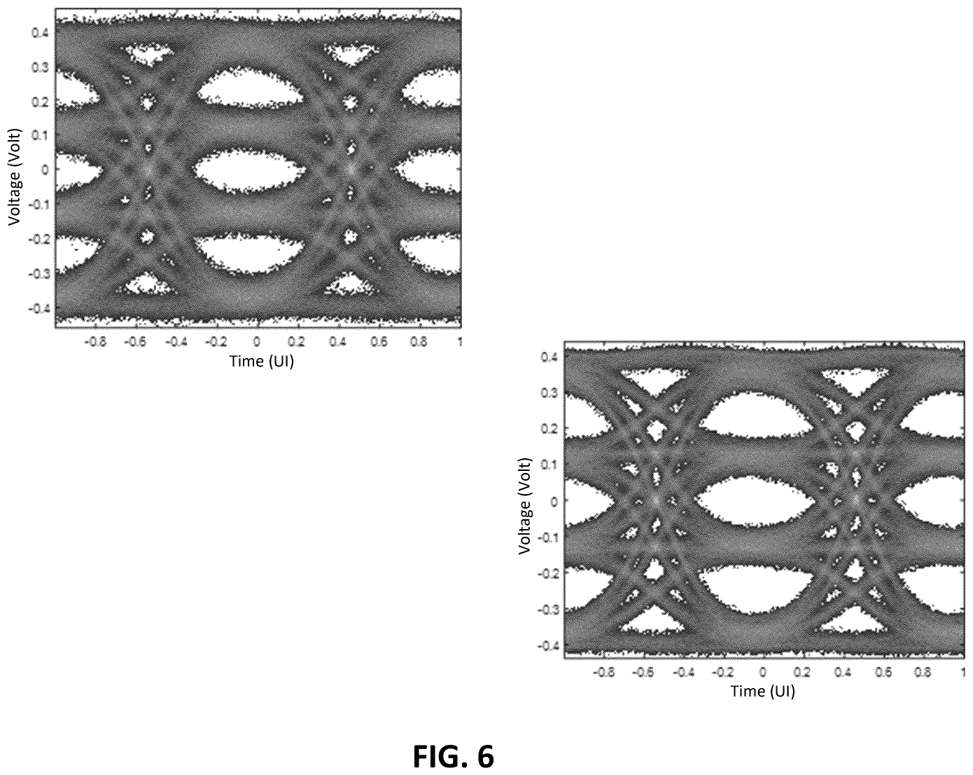

Upon obtaining the oscilloscope noise compensated spectrum, the process then converts the oscilloscope noise compensated waveform spectrum to time domain waveform, such as through inverse FFT. The new waveform comprises the oscilloscope noise compensated waveform. FIG. 6 shows the eye diagrams before, left, and after, right, applying the oscilloscope noise compensation. The eye diagram of the oscilloscope noise compensated waveform shows larger eye opening. The performance of the DUT can then be measured, such as measuring the symbol error rate, SNDR, TDECQ, and EVM.

In this manner, the embodiments allow the oscilloscope to improve the measurement fidelity by compensating the instrument random noise. The embodiments apply to both electrical and optical signals, and the signals could have various modulation schemes. For example, the EVM results could be improved once the oscilloscope noise gets compensated in the I and Q waveforms. The embodiments provide more accurate measurement, improve the instrument sensitivity, improve measurement margin, and increase product yield. The improved instrument sensitivity allows the same instrument to measure the smaller signals and the signals with higher noise than the instrument with lower sensitivity. The instrument sensitivity is key specification for optical signal measurement, but applies to optical and electronic devices, allowing for more accurate testing.

Aspects of the disclosure may operate on a particularly created hardware, on firmware, digital signal processors, or on a specially programmed general-purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is an oscilloscope, comprising: one or more ports to connect the oscilloscope to a device under test (DUT); one or more analog-to-digital converter (ADC) to receive a signal from the DUT, sample the signal, and produce digital samples of the signal as a waveform; and one or more processors configured to execute code that causes the one or more processors to: acquire a noise waveform for the oscilloscope when there is no input signal and determine a measure of the noise waveform; acquire a waveform with multiple repetitions of a repeating pattern from the one or more ADCs; determine a frequency spectrum of the waveform; identify spectral impulses in the frequency spectrum of the waveform associated with the repeating pattern as a spectral impulse portion of the frequency spectrum; determine a measure of a flat portion of the frequency spectrum not associated with the repeating pattern; use the measure of the flat portion of the frequency spectrum and the measure of the noise waveform to produce a noise compensation ratio; scale the flat portion of the frequency spectrum with the noise compensation ratio and combine the scaled flat portion with the spectral impulse portion of the frequency spectrum to produce a noise compensated waveform frequency spectrum; convert the noise compensated waveform frequency spectrum to a time domain noise compensated waveform; and use the time domain noise compensated waveform to measure performance of the DUT.

Example 2 is the oscilloscope of Example 1, further comprising an optical to electrical converter to convert an optical signal from the DUT to an electrical signal.

Example 3 is the oscilloscope of either of Examples 1 or 2, wherein the repeating pattern comprises a compliance pattern for a standard.

Example 4 is the oscilloscope of any of Examples 1 through 3, wherein the code that causes the one or more processors to determine a measure of the noise waveform comprises code to cause the one or more processors to calculate one of either a root mean square of the noise waveform for optical signal type, or a standard deviation of the noise waveform for electrical signal type.

Example 5 is the oscilloscope of any of Examples 1 through 4, wherein the code that causes the one or more processors to determine a frequency spectrum of the waveform comprises code to cause the one or more processors to perform a Fast Fourier Transform on the waveform.

Example 6 the oscilloscope of any of Examples 1 through 5, wherein the code that causes the one or more processors to determine a measure of a flat portion of the frequency spectrum comprises code to cause the one or more processors to calculate a root mean square of the flat portion of the frequency spectrum.

Example 7 the oscilloscope of any of Examples 1 through 6, wherein the code that causes the one or more processors to use the measure of the flat portion of the frequency spectrum and the measure of the noise waveform comprises code that causes the one or more processors to calculate the square root of the measure of the flat portion squared minus the measure of the noise waveform squared, divided by the measure of the flat portion.

Example 8 the oscilloscope of Example 7, wherein the one or more processors are further configured to execute code that causes the one or more processors to scale the measure of the flat portion of the frequency spectrum to partially compensate for noise caused by the oscilloscope.

Example 9 is the oscilloscope of any of Examples 1 through 8, wherein the code that causes the one or more processors to use the time domain compensated waveform to measure performance of the DUT comprises code to cause the one or more processors to measure one or more of a symbol error rate, signal to noise distortion rate, transmitter and dispersion eye closure quaternary, and error vector magnitude.

Example 10 is a method, comprising: acquiring a noise waveform for an oscilloscope when there is no input signal and determine a measure of the noise waveform; acquiring a waveform from a device under test (DUT) with multiple repetitions of a repeating pattern; determining a frequency spectrum of the waveform; identifying spectral impulses in the frequency spectrum of the waveform associated with the repeating pattern as a spectral impulse portion of the frequency spectrum; determining a measure of a flat portion of the frequency spectrum not associated with the repeating pattern; using the measure of the flat portion of the frequency spectrum and the measure of the noise waveform to produce a noise compensation ratio; scaling the flat portion of the frequency spectrum with the noise compensation ratio and combining the flat portion with the spectral impulse portion of the frequency spectrum to produce a noise compensated waveform frequency spectrum; converting the noise compensated waveform frequency spectrum to a time domain noise compensated waveform; and using the time domain noise compensated waveform to measure performance of the DUT.

Example 11 is the method of Example 10, further comprising using an optical to electrical converter to convert an optical signal from the DUT to an electrical signal.

Example 12 is the method of either of Examples 10 or 11, wherein the repeating pattern comprises a compliance pattern for a standard.

Example 13 is the method of any of Examples 10 through 12, wherein determining a measure of the noise waveform comprises calculating a root mean square of the noise waveform.

Example 14 is the method of any of Examples 10 through 13, wherein determining a frequency spectrum of the waveform comprises performing a Fast Fourier Transform on the waveform.

Example 15 is the method of any of Examples 10 through 14, wherein determining a measure of a flat portion of the frequency spectrum comprises calculating one or either a root mean square of the flat portion of the frequency spectrum for optical signal type, or a standard deviation of the noise waveform for electrical signal type.

Example 16 is the method of any of Examples 10 through 15, wherein using the measure of the flat portion of the frequency spectrum and the measure of the noise waveform comprises calculating the square root of the measure of the flat portion squared minus the measure of the noise waveform squared, divided by the measure of the flat portion.

Example 17 is the method of Example 16, further comprising scaling the measure of the flat portion to partially compensate for noise caused by the oscilloscope.

Example 18 is the method of any of Examples 10 through 17, wherein using the time domain compensated waveform to measure performance of the DUT comprises measuring one or more of a symbol error rate, signal to noise distortion rate, transmitter and dispersion eye closure quaternary, and error vector magnitude.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific examples of the invention have been illustrated and described for purposes of illustration, it will be understood that various modifications may be made without departing from the spirit and scope of the invention. Accordingly, the invention should not be limited except as by the appended claims.

1. An oscilloscope, comprising:
one or more ports to connect the oscilloscope to a device under test (DUT);
one or more analog-to-digital converter (ADC) to receive a signal from the DUT, sample the signal, and produce digital samples of the signal as a waveform; and
one or more processors configured to execute code that causes the one or more processors to:
acquire a noise waveform for the oscilloscope when there is no input signal and determine a measure of the noise waveform;
acquire a waveform with multiple repetitions of a repeating pattern from the one or more ADCs;
determine a frequency spectrum of the waveform;
identify spectral impulses in the frequency spectrum of the waveform associated with the repeating pattern as a spectral impulse portion of the frequency spectrum;
determine a measure of a flat portion of the frequency spectrum not associated with the repeating pattern;
use the measure of the flat portion of the frequency spectrum and the measure of the noise waveform to produce a noise compensation ratio;
scale the flat portion of the frequency spectrum with the noise compensation ratio and combine the scaled flat portion with the spectral impulse portion of the frequency spectrum to produce a noise compensated waveform frequency spectrum;
convert the noise compensated waveform frequency spectrum to a time domain noise compensated waveform; and
use the time domain noise compensated waveform to measure performance of the DUT.

2. The oscilloscope as claimed in claim 1, further comprising an optical to electrical converter to convert an optical signal from the DUT to an electrical signal.

3. The oscilloscope as claimed in claim 1, wherein the repeating pattern comprises a compliance pattern for a standard.

4. The oscilloscope as claimed in claim 1, wherein the code that causes the one or more processors to determine a measure of the noise waveform comprises code to cause the one or more processors to calculate one of either a root mean square of the noise waveform for optical signal type, or a standard deviation of the noise waveform for electrical signal type.

5. The oscilloscope as claimed in claim 1, wherein the code that causes the one or more processors to determine a frequency spectrum of the waveform comprises code to cause the one or more processors to perform a Fast Fourier Transform on the waveform.

6. The oscilloscope as claimed in claim 1, wherein the code that causes the one or more processors to determine a measure of a flat portion of the frequency spectrum comprises code to cause the one or more processors to calculate a root mean square of the flat portion of the frequency spectrum.

7. The oscilloscope as claimed in claim 1, wherein the code that causes the one or more processors to use the measure of the flat portion of the frequency spectrum and the measure of the noise waveform comprises code that causes the one or more processors to calculate the square root of the measure of the flat portion squared minus the measure of the noise waveform squared, divided by the measure of the flat portion.

8. The oscilloscope as claimed in claim 7, wherein the one or more processors are further configured to execute code that causes the one or more processors to scale the measure of the flat portion of the frequency spectrum to partially compensate for noise caused by the oscilloscope.

9. The oscilloscope as claimed in claim 1, wherein the code that causes the one or more processors to use the time domain compensated waveform to measure performance of the DUT comprises code to cause the one or more processors to measure one or more of a symbol error rate, signal to noise distortion rate, transmitter and dispersion eye closure quaternary, and error vector magnitude.

10. A method, comprising:
acquiring a noise waveform for an oscilloscope when there is no input signal and determine a measure of the noise waveform;
acquiring a waveform from a device under test (DUT) with multiple repetitions of a repeating pattern;
determining a frequency spectrum of the waveform;
identifying spectral impulses in the frequency spectrum of the waveform associated with the repeating pattern as a spectral impulse portion of the frequency spectrum;
determining a measure of a flat portion of the frequency spectrum not associated with the repeating pattern;
using the measure of the flat portion of the frequency spectrum and the measure of the noise waveform to produce a noise compensation ratio;
scaling the flat portion of the frequency spectrum with the noise compensation ratio and combining the flat portion with the spectral impulse portion of the frequency spectrum to produce a noise compensated waveform frequency spectrum;
converting the noise compensated waveform frequency spectrum to a time domain noise compensated waveform; and
using the time domain noise compensated waveform to measure performance of the DUT.

11. The method as claimed in claim 10, further comprising using an optical to electrical converter to convert an optical signal from the DUT to an electrical signal.

12. The method as claimed in claim 10, wherein the repeating pattern comprises a compliance pattern for a standard.

13. The method as claimed in claim 10, wherein determining a measure of the noise waveform comprises calculating a root mean square of the noise waveform.

14. The method as claimed in claim 10, wherein determining a frequency spectrum of the waveform comprises performing a Fast Fourier Transform on the waveform.

15. The method as claimed in claim 10, wherein determining a measure of a flat portion of the frequency spectrum comprises calculating one or either a root mean square of the flat portion of the frequency spectrum for optical signal type, or a standard deviation of the noise waveform for electrical signal type.

16. The method as claimed in claim 10, wherein using the measure of the flat portion of the frequency spectrum and the measure of the noise waveform comprises calculating the square root of the measure of the flat portion squared minus the measure of the noise waveform squared, divided by the measure of the flat portion.

17. The method as claimed in claim 16, further comprising scaling the measure of the flat portion to partially compensate for noise caused by the oscilloscope.

18. The method as claimed in claim 10, wherein using the time domain compensated waveform to measure performance of the DUT comprises measuring one or more of a symbol error rate, signal to noise distortion rate, transmitter and dispersion eye closure quaternary, and error vector magnitude.
